(19) United States
(12) Patent Application Publication
(10) Pub. No.: US 2012/0327607 A1
(43) Pub. Date: Dec. 27, 2012

(54) PACKAGE STRUCTURE OF TRANSIENT VOLTAGE SUPPRESSOR

(76) Inventors: Ho-Shyan LIN, Taipei City (TW); Tsu-Yang Wong, Hsinchu City (TW)

(21) Appl. No.: 13/166,480

(22) Filed: Jun. 22, 2011

(51) Int. Cl. H05K 7/00

(52) U.S. Cl. 361/728

(57) ABSTRACT

A package structure of transient voltage suppressor is disclosed. The package structure comprises a package housing with a bottom thereof having a first contact pin, a second contact pin, and a third contact pin, wherein the third contact pin is positioned between the first contact pin and the second contact pin. A first diode is positioned in the package housing, and an anode and a cathode of the first diode are respectively connected with the third contact pin and the first contact pin. A second diode is installed in the package housing, and an anode and a cathode of the second diode are respectively connected with the third contact pin and the second contact pin.

### BACKGROUND OF THE INVENTION

1. Field of the Invention

The present invention relates to a package structure, particularly to a package structure of transient voltage suppressor.

2. Description of the Related Art

Because the IC device sizes have been shrunk to nanometer scale, the consumer electronics, like the laptop and mobile devices, have been designed to be much smaller than ever. Without suitable protection devices, the functions of these electronics could be reset or even damaged under ESD (Electrostatic Discharge) events. Currently, all consumer electronics are expected to pass the ESD test requirement of IEC 61000-4-2 standard. TVS (Transient Voltage Suppressor) is generally designed to bypass the ESD energy, so that the electronic systems can be prevented from ESD damages.

In the prior art, the TVS is only a diode to pass positive or negative surge signals, as shown in FIG. 1. A diode 10 is installed between a signal terminal 12 and an electric circuit 14 to pass the positive surge signal when the ESD event occurs. Although the TVS comprising a diode can save space, the TVS only pass a single polar surge signal. The design is disclosed in U.S. Pat. No. 4,600,960. Additionally, as shown in FIG. 2, when a positive or negative surge signal appear at a signal terminal 16, a first diode 18 and a second diode 20 installed between the signal terminal 16 and an electric circuit 22 are required, wherein the two diodes 18 and 20 are connected inversely. The first diode 18 and the second diode 20 can respectively pass the positive or negative surge signal. However, the circuit board or the integrated circuit needs a larger space to install the two diodes 18 and 20. This design is not suitable to the nanometer scale technology nowadays. Besides, the signal quality will be degraded due to the asymmetric arrangement of the design.

To overcome the abovementioned problems, the present invention provides a package structure of transient voltage suppressor, so as to solve the afore-mentioned problems of the prior art.

### SUMMARY OF THE INVENTION

A primary objective of the present invention is to provide a package structure of transient voltage suppressor, which only has three pins paralleled with each other and a small volume to save space. When the package structure is installed between a driver and a connector, wires can be running and connected directly to the pins. And, the easy circuit layout of the transient voltage suppressor is further suitable for differential signals.

To achieve the abovementioned objectives, the present invention provides a package structure of transient voltage suppressor, which comprises a package housing with a bottom thereof having a first contact pin, a second contact pin, and a third contact pin, wherein the third contact pin is positioned between the first contact pin and the second contact pin. A first diode is positioned in the package housing, and an anode and a cathode of the first diode are respectively connected with the third contact pin and the first contact pin. A second diode is installed in the package housing, and an anode and a cathode of the second diode are respectively connected with the third contact pin and the second contact pin.

Below, the embodiments are described in detail in cooperation with the drawings to make easily understood the technical contents, characteristics and accomplishments of the present invention.

### BRIEF DESCRIPTION OF THE DRAWINGS

FIG. 1 is a circuit diagram showing a transient voltage suppressor connected with an electric circuit according to the prior art;

FIG. 2 is a circuit diagram showing two transient voltage suppressor connected with an electric circuit according to the prior art;

FIG. 3 is a perspective view showing a package structure of a transient voltage suppressor according to the first embodiment of the present invention;

FIG. 4 is a circuit and bonding layout showing the package structure of the transient voltage suppressor according to the first embodiment of the present invention;

FIG. 5 is a circuit diagram showing the transient voltage suppressor according to the first embodiment of the present invention;

FIG. 6 is a perspective view showing a package structure of a transient voltage suppressor according to the second embodiment of the present invention;

FIG. 7 is a circuit and bonding layout showing the package structure of the transient voltage suppressor according to the second embodiment of the present invention; and

FIG. 8 is a circuit block diagram showing the transient voltage suppressor connected with a high definition multimedia (HDMI) driver and a HDMI connector according to an embodiment of the present invention.

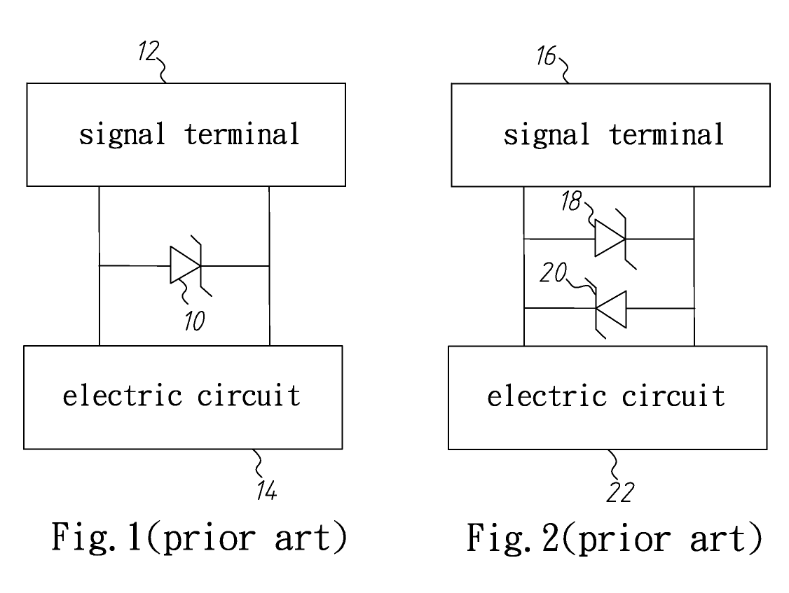

### DETAILED DESCRIPTION OF THE INVENTION

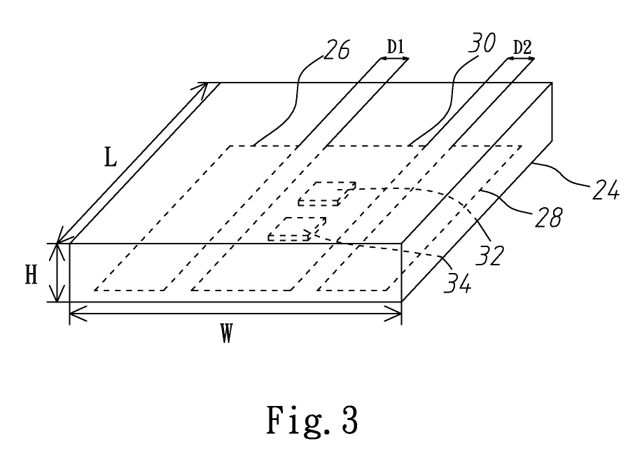

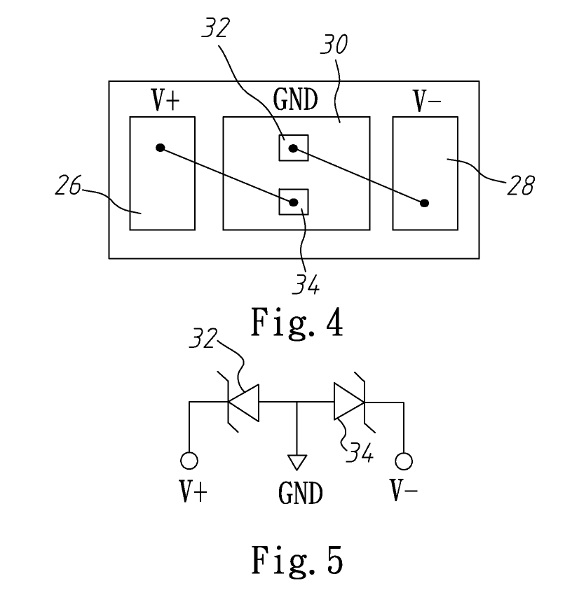

Refer to FIG. 3, FIG. 4, and FIG. 5. Below is described the first embodiment of the present invention. The package structure of transient voltage suppressor (TVS) of the present invention comprises a package housing 24 with a bottom thereof having a first contact pin 26, a second contact pin 28, and a third contact pin 30, wherein package housing 24 has a shape of cuboid. The third contact pin 30 is positioned between the first contact pin 26 and the second contact pin 28, wherein the contact pins 26, 28, and 30 are located on the same side. And, the first contact pin 26, the third contact pin 30, and the second contact pin 28 are paralleled with each other. For designing symmetrically, the first and second contact pins 26 and 28 are respectively connected with a positive voltage V+ and a negative voltage V−, and the third contact pin 30 is grounded GND.

There are two diodes installed in the package housing 24. The two diodes comprise a first diode 32 and a second diode 34, wherein the first and second diodes 32 and 34 are Zener diodes or a combination of diodes and Zener diodes. In the first embodiment, the first diode 32 and the second diode 34 are installed in the package housing 24 and disposed on the third contact pin 30. The first and second diodes 32 and 34 of the present invention are disposed on the third contact pin 30, which is used as an example, but the scope of the present invention is not so limited. An anode and a cathode of the first diode 32 are respectively connected with the third contact pin 30 and the first contact pin 26. An anode and a cathode of the second diode 34 are respectively connected with the third contact pin 30 and the second contact pin 28.

For the size design, the package housing 24 has a length L, a width W, and a height H. The length L ranges from 0.45 mm to 1.75 mm. The width W ranges from 0.25 mm to 0.85 mm. The height H is larger than 0 and not larger than 0.8 mm. A distance between the first contact pin 26 and the third contact pin 30 is larger than 0.2 mm and less than 0.65 mm. A distance between the second contact pin 28 and the third contact pin 30 is larger than 0.2 mm and less than 0.65 mm. Although the package structure has three pins, the volume of the structure is very small to save space.

Since the first contact pin 26 and the second contact pin 28 are symmetrical to the third contact pin 30, the loading capacitances correspond to the pin locations are symmetry. The loading capacitances usually affect the signal quality on the traces, especially for high speed differential signals. The parallel pins allow the signal traces to be parallel for positive and negative differential signals which also increase the trace signal quality. Small form factor package usually suffers the symmetry to give room for the third pins and this invention conquers the difficulties in symmetry. Accordingly, the signal quality is enhanced and the noise is degraded due to the symmetric parasitic capacitance of the diodes 32 and 34. The easy layout of the present invention is best for differential signal. Besides, the package structure of the present invention is also suitable for 0402 size package due to the small volume, wherein 0402 is a model number of the package structure in the market.

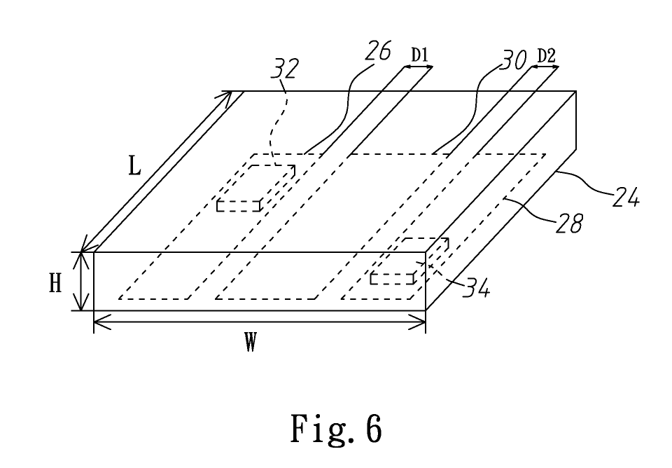

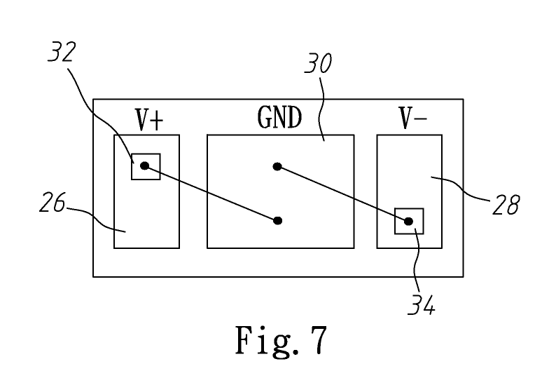

The second embodiment is introduced as below. Refer to FIG. 6 and FIG. 7. The second embodiment is different from the first embodiment in the positions of the first and second diodes 32 and 34. In the second embodiment, the first diode 32 and the second diode 34 are respectively disposed on the first contact pin 26 and the second contact pin 28. The equivalent circuit of the second embodiment is the same to the first embodiment, as shown in FIG. 5. Since the first and second embodiments have the same pin positions, the second embodiment can be achieved to the efficiency that the first embodiment has.

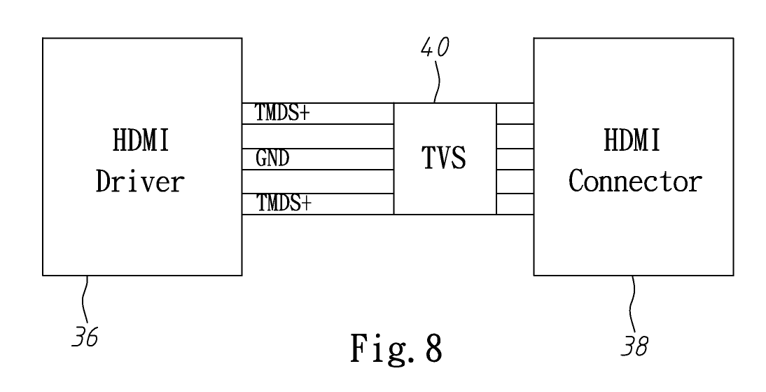

Refer to FIG. 8. The package structure 40 of transient voltage suppressor of the present invention can be applied to a High Definition Multimedia (HDMI) driver 36 and a HDMI connector 38. The HDMI driver 36 is connected with the HDMI connector 38 via three wires. The three wires have three kinds of voltages, which denoted by Transition Minimized Differential Signaling (TMDS)+, GND, and TMDS−. The wire having GND voltage is located between the other wires. Since the package structure 40 has three pins corresponding to the three wires, the wires can be running and connected directly to the pins. The application of this invention is not limited to HDMI, it can be applied to all differential signal pairs. For example, the USB2.0 has 3 differential pairs, the Thunderbolt signal pairs, the PCI express signal pairs, the SATA signal pairs and many other applications. This invention is more useful for high speed signal pairs.

In conclusion, the present invention not only has three parallel and symmetric pins to benefit the signal performance but simplifies wires arrangement in the circuit design.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A package structure of transient voltage suppressor, comprising:
a package housing having a first contact pin, a second contact pin, and a third contact pin, wherein said third contact pin is positioned between said first contact pin and said second contact pin;
a first diode positioned in said package housing, and an anode and a cathode of said first diode are respectively connected with said third contact pin and said first contact pin; and
a second diode installed in said package housing, and an anode and a cathode of said second diode are respectively connected with said third contact pin and said second contact pin.

2. The package structure of transient voltage suppressor according to claim 1, wherein said first contact pin, said third contact pin, and said second contact pin are paralleled with each other.

3. The package structure of transient voltage suppressor according to claim 1, wherein said package housing has a length of between 0.45 mm and 1.75 mm.

4. The package structure of transient voltage suppressor according to claim 1, wherein said package housing has a width of between 0.25 mm and 0.85 mm.

5. The package structure of transient voltage suppressor according to claim 1, wherein said package housing has a height larger than 0 and not larger than 0.8 mm.

6. The package structure of transient voltage suppressor according to claim 1, wherein said package housing has a shape of a cuboid.

7. The package structure of transient voltage suppressor according to claim 1, wherein a distance between said first contact pin and said third contact pin is larger than 0.2 mm and less than 0.65 mm, and wherein a distance between said second contact pin and said third contact pin is larger than 0.2 mm and less than 0.65 mm.

8. The package structure of transient voltage suppressor according to claim 1, wherein said first diode and said second diode are installed in said package housing and disposed on said third contact pin.

9. The package structure of transient voltage suppressor according to claim 1, wherein said first diode is disposed on said first contact pin, and wherein said second diode is disposed on said second contact pin.

10. The package structure of transient voltage suppressor according to claim 1, wherein said first diode and said second diode are Zener diodes or a combination of diodes and Zener diodes.

11. The package structure of transient voltage suppressor according to claim 1, wherein said first and second contact pins are respectively connected with a positive voltage and a negative voltage, and said third contact pin is grounded.
